(19) United States
(12) Patent Application Publication
(10) Pub. No.: US 2018/0114883 A1
(43) Pub. Date: Apr. 26, 2018

(54) CONVERTER COMPONENT FOR AN OPTO-ELECTRONIC LIGHTING DEVICE

(71) Applicant: OSRAM Opto Semiconductors GmbH, Regensburg (DE)

(72) Inventors: Markus Richter, Burglengenfeld (DE); Martin Brandl, Kelheim (DE); Markus Burger, Laaber (DE); Günter Spath, Regensburg (DE)

(21) Appl. No.: 15/565,523

(22) PCT Filed: Apr. 7, 2016
(86) PCT No.: PCT/EP2016/057638

§ 371 Date: Oct. 10, 2017

(30) Foreign Application Priority Data
Apr. 10, 2015 (DE) 10 2015 105 474.4

(51) Int. Cl. H01L 33/50

(52) U.S. Cl. CPC H01L 33/50; H01L 2933/0091; H01L 2933/0041

(57) ABSTRACT

A converter component for an opto-electronic lighting device includes an auxiliary carrier, wherein a layer stack including a base layer and a converter layer is formed on a surface of the auxiliary carrier. An opto-electronic lighting device includes a light-emitting semiconductor component and the converter component for an opto-electronic light device including an auxiliary carrier, wherein a layer stack including a base layer and a converter layer is formed on a surface of the auxiliary carrier with a removed auxiliary carrier.

### TECHNICAL FIELD

This disclosure relates to a converter component for an opto-electronic lighting device, a method of producing a converter component for an opto-electronic lighting device, and an opto-electronic lighting device.

### BACKGROUND

More and more LED (light emitting diode) components require a cover for a light-emitting chip with a strictly defined conversion layer. In this case, in addition to the exact color location, new properties such as the layer thickness, the contour fidelity, the dimensional accuracy or the appearance in the switched-off state, also play a very important role.

Conversion elements with a defined outer contour used as a stop edge for potting material in a process of potting the component up to the conversion element surface, are also a very important requirement. Such a stop edge may furthermore also be necessary, for example, in other processes, for example, in so-called “film-assisted molding.”

With the aid of technologies, for example, screen or stencil printing, spraying, injection-molding, nozzle jet methods, it is only possible to meet some of the necessary requirements, which always results in compromise solutions. For example, conversion elements having shape fidelity and having a well-defined layer thickness can be produced very easily using screen and stencil printing. However, the nature of the surface and the edges of the element is unsuitable for the new requirements.

In particular, these technologies cannot be used to produce conversion elements with sharp outer edges that can be used as a stop edge for the potting process, for example, or film-assisted molding.

Although it is possible to produce conversion layers using small ceramic converter plates, they are expensive and cannot cover all color locations.

It could therefore be helpful to provide a reproducible and homogeneous appearance of a converter component and efficient suitability of the converter component to process processes, in particular a potting process and/or film-assisted molding.

### SUMMARY

We provide a converter component for an opto-electronic lighting device including an auxiliary carrier, wherein a layer stack including a base layer and a converter layer is formed on a surface of the auxiliary carrier.

We also provide a method of producing a converter component for an opto-electronic lighting device including providing an auxiliary carrier, and forming a layer stack including a base layer and a converter layer on a surface of the auxiliary carrier.

We further provide an opto-electronic light device including a light-emitting semiconductor component and the converter component for an opto-electronic light device including an auxiliary carrier, wherein a layer stack including a base layer and a converter layer is formed on a surface of the auxiliary carrier with a removed auxiliary carrier.

### BRIEF DESCRIPTION OF THE DRAWINGS

FIGS. 1-4 each show a production step in a method of producing a first converter component.

FIGS. 5-8 each show a production step in a method of producing a second converter component.

FIGS. 9-13 each show a production step in a method of producing a third converter component.

FIGS. 14-18 each show a production step in a method of producing a fourth converter component.

FIGS. 19-22 each show a production step in a method of producing a fifth converter component.

FIGS. 23-25 each show a production step in a method of producing a sixth converter component.

FIG. 26 shows a production step in a method of producing a seventh converter component.

FIGS. 27 and 28 each show a production step in a method of producing an eighth converter component.

FIG. 29 shows a flowchart of a method of producing a converter component.

FIG. 30 shows an opto-electronic lighting device.

### LIST OF REFERENCE SYMBOLS

101 Auxiliary carrier
103 Surface of the auxiliary carrier
105 Silicone layer
107 Underside of the silicone layer
109 Top side of the silicone layer
201 Converter layer
203 Underside of the converter layer
205 Top side of the converter layer
207 Converter component
209 Layer stack
301 Recess
303 Singulated converter component
401 Light source
403 Optical detector
405 Emitted light cone of the light source
407 Reflected light
501 Silicone layer
503 Underside of the silicone layer
505 Top side of the silicone layer
507 Diffuser particles
601 Layer stack
603 Converter component
701 Saw
801 Singulated converter component
1001 Diffuser layer
1003 Underside of the diffuser layers
1005 Top side of the diffuser layers
1101 Layer stack
1103 Converter component
1201 Singulated converter component
1601 Layer stack
1603 Converter component
1801 Singulated converter component
2001 Layer stack
2003 Converter component
2101 Singulated converter component]
2301 Layer stack
2303 Converter component
2501 Singulated converter component
2601 Layer stack
2603 Converter component
2801 Layer stack
2803 Converter components
2901 Providing
2903 Forming
3001 Opto-electronic lighting device
3003 Light-emitting semiconductor component
3005 Converter component with removed auxiliary carrier
3007 Primary radiation
3009 Secondary radiation

### DETAILED DESCRIPTION

We provide a converter component for an opto-electronic lighting device that may comprise:

an auxiliary carrier, wherein

a layer stack comprising a base layer and a converter layer is formed on a surface of the auxiliary carrier.

We also provide a method of producing a converter component for an opto-electronic lighting device comprising:

providing an auxiliary carrier,

forming a layer stack comprising a base layer and a converter layer on a surface of the auxiliary carrier.

We further provide an opto-electronic lighting device comprising a light-emitting semiconductor component and the converter component with a removed auxiliary carrier.

We therefore provide in particular forming a layer stack comprising a base layer and a converter layer on a surface of an auxiliary carrier.

In particular, efficient component-specific assembly is achieved on account of the layer stack. This is because, on account of the use of at least two layers for the layer stack, layer thicknesses can be advantageously adapted in accordance with the component requirements, the converters used and the color locations to be achieved. There is therefore a high degree of flexibility with respect to a layer thickness for the layer stack. For example, layer stacks may have an identical thickness for different color locations which are generally achieved by different layer thicknesses of the converter layer. The common thickness of the layer stacks can then be achieved, for example, by appropriately adapting the layer thickness of the base layer.

Furthermore, such a layer stack can be efficiently singulated to form singulated layer stacks on a common auxiliary carrier, with the result that very good contour fidelity can be achieved for the singulated layer stacks, for example. In particular, stop edges for subsequent potting processes can be efficiently produced. In particular, quick adaptation to desired dimensions can be carried out.

The auxiliary carrier may be a film, for example, a polyimide film, a polytetrafluoroethylene film, a UV film, a sawing film, a so-called “thermal release film” (an adhesive film which can be released from the object (here the layer stack), to which the adhesive film is adhesively bonded, by heating).

A thickness of the auxiliary carrier is 50 μm and 500 μm, for example.

The auxiliary carrier is, in particular, a temporary carrier and is removed again in a subsequent method step, for example.

The layer stack, in particular the singulated layer stacks, may be removed from the auxiliary carrier and arranged on a further auxiliary carrier.

The arrangement on the further auxiliary carrier comprises, for example, adhesively bonding the layer stack, in particular the singulated layer stacks, to the further auxiliary carrier.

The base layer may be a silicone layer. If the structure comprises a silicone layer below, the more general term “base layer” should always be inferred. A silicone layer has the technical advantage, in particular, that it can be efficiently produced.

The base layer may comprise at least one of the following materials or is formed from at least one of the following materials: silicone, glass, hybrid materials (for example, glass/silicone).

A layer stack therefore comprises, in particular, a plurality of layers, here, in particular, the base layer, preferably the silicone layer, and the converter layer, stacked on top of one another. That is to say, the individual layers of the layer stack are stacked.

A converter layer is configured, in particular, to convert electromagnetic radiation having a first wavelength or a first wavelength range into electromagnetic radiation having a second wavelength or a second wavelength range, the second wavelength differing from the first wavelength or the second wavelength range differing at least partially, in particular completely, from the first wavelength range. A converter layer therefore has a converter function or a conversion function, that is to say converts electromagnetic radiation. The electromagnetic radiation to be converted may be referred to as primary light or primary radiation, for example. The electromagnetic radiation converted by the converter layer can be referred to as secondary light or secondary radiation, for example. On account of the conversion function, a converter layer may also be referred to as a conversion layer.

The primary radiation is 430 nm to 480 nm, for example.

The secondary radiation is 450 nm to 800 nm, for example.

One example provides for the base layer, for example, the silicone layer, to be free of a diffuser. That is to say, in particular, a diffuser is not situated in the base layer. This achieves the technical advantage, in particular, that electromagnetic radiation radiating through the base layer is scarcely scattered or is not scattered at all in the base layer. That is to say, the base layer is transparent. Transparent can also be referred to as clear. That is to say, the base layer which is free of a diffuser is a clear base layer. Transparent means, in particular, that the base layer has a transmission of 90%, in particular 95%, preferably 99%, of the primary radiation and/or secondary radiation.

Another example provides for the base layer to comprise a diffuser. This achieves the technical advantage, in particular, that electromagnetic radiation radiating through the base layer can be scattered in the base layer. This makes it possible to achieve a homogeneous optical appearance, for example.

The diffuser may be formed, for example, such that it generates a particular color, for example, white. This makes it possible to conceal the converter layer, for example. In particular, as a result, the opto-electronic lighting device may have a particular color impression in the switched-off state.

Another example provides for the layer stack to comprise a diffuser layer comprising a diffuser. This achieves the technical advantage, in particular, that electromagnetic radiation radiating through the layer stack can be scattered. This makes it possible to achieve a homogeneous optical impression, for example.

One example provides for the layer stack to be free of a diffuser layer comprising a diffuser. That is to say, the layer stack does not have a diffuser layer comprising a diffuser.

Another example provides for the diffuser to comprise one or more diffuser particles, in particular: SiO₂ particles, Al₂O₃ particles, THIO₂ particles, silicone particles, glass particles. Providing one or more diffuser particles achieves the technical advantage, in particular, that electromagnetic radiation is efficiently scattered. In particular, a different degree of scattering or scattering cross section can be set by providing different particle sizes. For example, a diffuser particle may comprise an average particle size of 100 nm to 10 μm. That is to say, in particular, a diameter of the diffuser particles may be 100 nm to 10 μm.

The above-mentioned materials for diffuser particles and, in particular, the different particle sizes can advantageously have different properties used according to the requirements. For example, Al₂O₃ makes a better contribution to homogenizing the light or generally the electromagnetic radiation. THIO₂ contributes to a better white impression in the switched-off state.

Another example provides for the converter layer to comprise silicone and a converter.

A converter is, in particular, a material or a material composition (that is to say generally a material) that converts electromagnetic radiation. A converter is a phosphor, for example. A converter is an organic or inorganic dye, for example. Converters are, in particular, powders (comprising, for example, phosphor and/or an inorganic and/or organic luminescent substance) which are fixed in a radiation-stable matrix. Silicone is particularly suitable as the matrix material in the exemplary range of the primary radiation stated above.

That is to say, in particular, the converter, for example, a powder, is embedded in silicone. The silicone therefore forms, in particular, a matrix in which the powder or generally the converter is preferably embedded.

Another example provides for at least one of the layers of the layer stack to have been sprayed on. For example, all layers of the layer stack have been sprayed on. For example, the base layer, in particular the silicone layer, is or has been sprayed on. Spraying-on has the technical advantage, in particular, that a layer thickness of the corresponding layer can be efficiently set. In particular, a color location can be advantageously efficiently set if the converter layer has been sprayed on. This is affected, in particular, using a predetermined layer thickness.

One example provides for at least one of the layers of the layer stack to be sprayed on. In particular, all layers of the layer stack are sprayed on.

In one example, the material to be sprayed on is comprised by a suspension sprayed on, for example, by a spray nozzle, as is also explained below.

The respective material used for the purpose of forming the one or more layers of the layer stack by spraying-on, or the respective suspension used and comprising the material to be sprayed on, has, in particular, a viscosity of, for example, at most 50 map*s at 20° C., for example, at most 40 map*s at 20° C., for example, at most 30 map*s at 20° C., for example, at most 20 map*s at 20° C., for example, at most 15 map*s at 20° C., for example, at most 10 map*s at 20° C., for example, at most 5 map*s at 20° C., in particular at most 3 map*s at 20° C., in particular at most 2 map*s at 20° C., for example, at most 1.5 map*s.

That is to say, in particular, the respective material for spraying-on is a spray able material or the suspension is a spray able suspension. This is in contrast to a paste-like material that spreads satisfactorily and can therefore be used for a screen printing method, for example. A screen printing method is therefore not spraying-on. Spraying-on is referred to as “spray coating.”

In one example, a spray gun is used to spray on the at least one layer, in particular all layers, of the layer stack.

A spray gun may comprise a spray nozzle. The spray nozzle is used to spray on the material or the suspension. During spraying-on, the spray nozzle is, for example, at a distance of one or more centimeters from the surface of the element onto which (the surface) the material or the suspension is sprayed, that is to say, for example, from the surface of the auxiliary carrier or the surface of a layer which has already been formed. That is to say, the material or the suspension is transferred in a contact less manner (the spray nozzle does not touch the surface) during spraying-on. The spraying-on is therefore based on contact less material transfer.

The spray gun may comprise a storage container in which the material to be sprayed on and/or a suspension comprising the material to be sprayed on is stored. The spray gun therefore has a material storage function.

The spray gun may comprise a homogenizer to homogenize the stored material and/or to homogenize the suspension comprising the material to be sprayed on. The spray gun therefore has a homogenization function.

The spray gun may comprise a conveying device to convey the material to be sprayed on and/or the suspension comprising the material to be sprayed on from the storage container to the spray nozzle. The spray gun therefore has a conveying function.

The spray gun may comprise a valve connected between the spray nozzle and the storage container. The valve can therefore open or close a path of the material to be sprayed on or the suspension to be sprayed on.

By its design, the spray nozzle predefines a spray weight and/or a shape of a spray cone.

On the basis of the explanations given above, it should therefore be even clear that spraying-on differs from printing technology in many aspects. In printing technology, the material to be applied is paste-like, that is to say spreads satisfactorily, but is not flowable. In contrast, a suspension comprising the material, for example, is used for the spraying-on, the suspension having a viscosity comparable to that of water, for example. Exemplary viscosity values are cited above.

Unlike in printing technology, spraying-on is based on contact less material transfer. The spray gun moves, in particular, one or more centimeters above the surface onto which spraying is carried out or intended to be carried out.

A spray gun used for spraying-on is or has been defined by three features, in particular: material storage, a valve and a spray nozzle.

In addition to the function of a storage container contained in the name, material storage also comprises, for example, a homogenization function and also conveying of the material or the suspension, for example.

The valve opens or closes a path of the material or the suspension to the spray nozzle.

Another example provides for the base layer to be formed as a base film. This achieves the technical advantage, in particular, that the base layer can be efficiently handled. In particular, such a base layer formed as a base film can be efficiently produced. This is affected, for example, using technologies known per se to produce films. Such technologies comprise, for example, printing, sheet drawing (extrusion process), rolling and a molding method. A base film also has the technical advantage that it is flexible and, as a result, can be easily applied to the auxiliary carrier.

Another example provides for the silicone layer to be formed as a silicone film. The corresponding advantages result in a manner similar to the base film.

The base layer (for example, the silicone layer), in particular the base film (for example, the silicone film), may have a layer thickness of 10 μm to 500 μm.

Another example provides for the converter layer to have a layer thickness of 10 μm to 200 μm.

Another example provides for the diffuser layer to have a layer thickness of 0.5 μm to 100 μm.

The above-mentioned layer thicknesses depend, in particular, on a desired color location and/or, in particular, on a desired total layer thickness (thickness of the layer stack).

One example provides for the diffuser layer to be formed as a diffuser film.

One example provides for the converter layer to be formed as a converter film.

Advantages and technical functionalities relating to the diffuser film and the converter film result in a manner similar to the base film or silicone film.

Examples relating to the converter component result in a similar manner from corresponding examples of the method and vice versa. That is to say, technical functionalities for the converter component emerge from corresponding technical functionalities of the method and vice versa.

One example provides for the converter component to be produced by the method of producing a converter component.

After the layer stack has been formed on the surface of the auxiliary carrier, one example provides for the auxiliary carrier to be removed from the layer stack or vice versa. That is to say, the layer stack is free of the auxiliary carrier after this removal step. Before removal, after the layer stack has been formed, in particular after the layer stack has been singulated, provision may be made, for example, for the layer stack, in particular the singulated layer stacks, to be arranged on a further auxiliary carrier before the auxiliary carrier is removed. This arrangement on the further auxiliary carrier comprises relamination and/or renewed adhesive bonding, for example.

One example provides for a singulated layer stack (or a plurality of singulated layer stacks) to be removed from the auxiliary carrier or from the further auxiliary carrier. The layer stacks can therefore be individually removed from the auxiliary carrier or from the further auxiliary carrier, for example. Removal of the singulated layer stacks can also be referred to as withdrawal or picking-off.

One example provides for the light-emitting semiconductor component to be a light-emitting diode (LED).

The light-emitting semiconductor component may be a laser diode. In particular, provision is made of a plurality of light-emitting semiconductor components that may be formed identically or preferably differently, for example.

That is to say, in particular, the converter component with a removed auxiliary carrier is arranged in an emission region of the light-emitting semiconductor component(s) to convert the electromagnetic radiation emitted by the light-emitting semiconductor component(s).

A plurality of converter components may be provided.

The converter component of the lighting device is produced using our method, for example.

A layer (for example, converter layer, diffuser layer, base layer, for example, silicone layer) of the layer stack comprises a top side and an underside opposite the top side. Depending on the arrangement of the layers in the layer stack among one another, the underside of one layer is arranged on the top side of another layer.

A position of a layer in the layer stack can be defined based on the auxiliary carrier, for example.

Silicones are poly(organo)siloxanes and a designation for a group of synthetic polymers in which silicon atoms are linked via oxygen atoms.

One example provides for the layer stack to be singulated. The layer stack is therefore singulated, in particular. That is to say, for example, that recesses running through the layer stack to the surface of the auxiliary carrier are formed in the layer stack. Layer stacks separated from one another and arranged on the common auxiliary carrier are therefore formed. These singulated layer stacks therefore form singulated converter components. The recesses can lead into the auxiliary carrier, for example, without completely separating the latter in the process.

The singulation can be carried out, for example, using a saw, a laser, a water jet and/or a die.

The above-described properties, features and advantages and the manner in which they are achieved become clearer and more clearly comprehensible in connection with the following description of the examples explained in more detail in connection with the drawings.

Identical reference symbols are used for identical features below.

The examples are described in connection with a silicone layer. It is pointed out that the more general term “base layer” should always be inferred instead of the silicone layer.

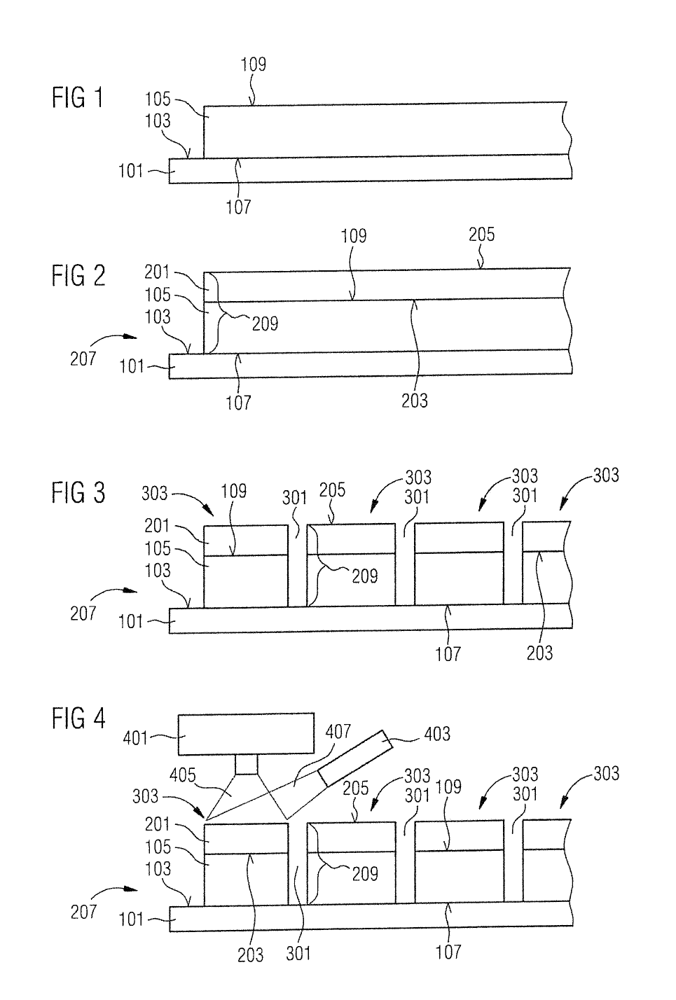

FIG. 1 shows a provided auxiliary carrier 101 having a surface 103. A silicone layer 105 is applied to the surface 103 as a base layer. The silicone layer 105 is formed as a silicone film, for example. The silicone layer 105 is free of a diffuser or is free of diffuser particles and is therefore clear.

The silicone layer 105 has an underside 107. The silicone layer 105 has a top side 109 which is formed opposite the underside 107. The silicone layer 105 is applied to the surface 103 such that the underside 107 faces the surface 103. The top side 109 of the silicone layer 105 faces away from the surface 103. That is to say, the underside 107 is applied to the surface 103.

The silicone layer 105 may be sprayed onto the surface 103, for example. In particular, the silicone layer 105 can be applied to the surface 103 if the silicone layer is formed as a silicone film.

A preferred thickness of the silicone layer 105 is 10 μm to 500 μm, for example.

FIG. 2 shows that a converter layer 201 is applied to the silicone layer 105. The converter layer 201 has an underside 203 and a top side 205 opposite the underside 203. The converter layer 201 is applied to the silicone layer 105 such that the underside 203 is opposite the top side 109 of the silicone layer 105. The top side 205 of the converter layer 201 faces away from the top side 109 of the silicone layer 105. That is to say, the underside 203 of the converter layer 201 is arranged on the top side 109 of the silicone layer 105.

The converter layer 201, generally also referred to as a conversion layer, can be sprayed onto the silicone layer 105, for example.

A layer stack 209 is therefore formed on the surface 103. This layer stack 209 comprises the silicone layer 105 and the converter layer 201. A converter component 207 comprising the auxiliary carrier 101 and the layer stack 209 is therefore produced. Based on the auxiliary carrier 101, a sequence of the layers of the layer stack 209 is as follows: first of all the silicone layer 105 and only then the conversion layer 201.

FIG. 3 shows the converter component 207 after a singulation step. In such a singulation step, the layer stack 209 is singulated. That is to say, the layer stack 209 is provided with recesses 301 running through the layer stack 209 to the surface 103 of the auxiliary carrier 101. Layer stacks separate from one another and arranged on the common auxiliary carrier 101 are therefore formed. These singulated layer stacks therefore form singulated converter components 303.

After this singulation step according to FIG. 3, electro-optical characterization of the singulated converter components 303 is provided according to FIG. 4.

This characterization comprises, for example, illuminating the singulated converter components 303 by light. A light source 401 is provided for this purpose. The light source 401 emits a light cone 405 in the direction of a top side 205 of a converter layer 201 of a singulated converter component 303. Light reflected by this top side 205 is symbolically indicated with the reference symbol 407. This reflected light is captured by an optical detector 403.

One example not shown provides for the singulated converter components 303 to be removed or detached from the auxiliary carrier 101. One example not shown provides for the singulated converter components 303 removed in this manner to be inserted or arranged in an opto-electronic lighting device.

FIGS. 5 to 8 each show a production step in a method of producing a second converter component.

FIG. 5 shows a provided auxiliary carrier 101, a silicone layer 501 being arranged on or applied to the surface 103 of the auxiliary carrier 101 as a base layer. In contrast to FIG. 1, the silicone layer 501 has diffuser particles 507. That is to say, diffuser particles are embedded in the silicone layer 501. These diffuser particles 507 scatter electromagnetic radiation.

The silicone layer 501 also has an underside 503 and a top side 505 opposite the underside 503. The underside 503 of the silicone layer 501 faces the surface 103. The top side 505 of the silicone layer 501 faces away from the surface 103 of the auxiliary carrier 101. That is to say, the silicone layer 501 is applied to the surface 103 as the first layer. The silicone layer 501 may be in the form of a silicone film, for example.

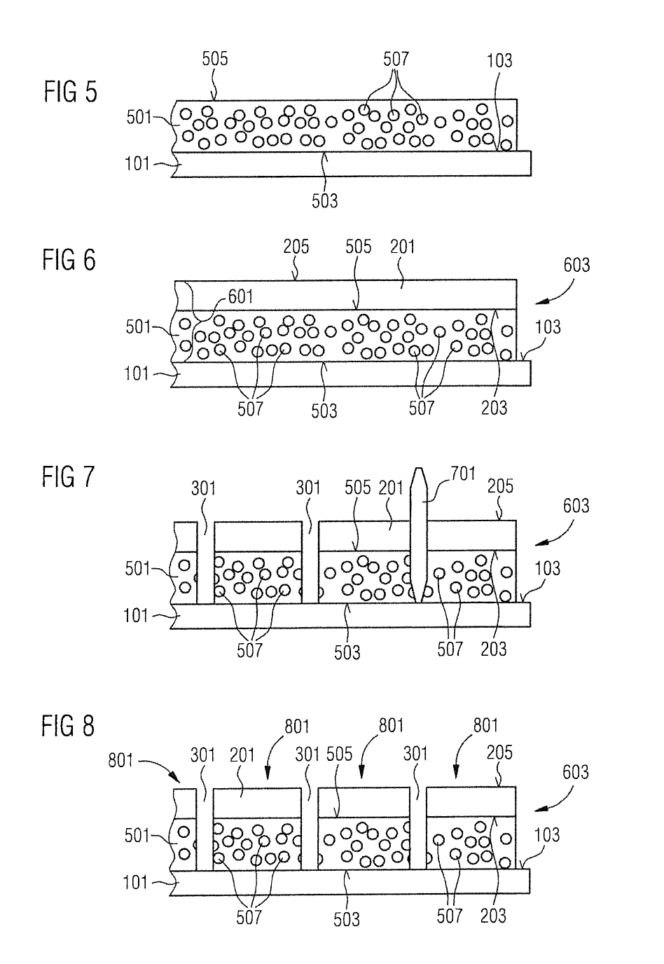

FIG. 6 shows a converter layer 201 applied to the top side 505 of the silicone layer 501 in a manner similar to FIG. 2. The underside 203 of the converter layer 201 therefore faces the top side 505 of the silicone layer 501. The top side 205 of the converter layer 201 faces away from the top side 505 of the silicone layer 501. That is to say, the converter layer 201 is applied after the silicone layer 501. A layer stack 601 comprising the silicone layer 501 and the converter layer 201 is therefore formed. This layer stack 601 is therefore formed on the surface 103 of the auxiliary carrier 101.

A converter component 603 comprising the auxiliary carrier 101 and the layer stack 601 is therefore produced. Based on the auxiliary carrier 101, a sequence of the layers of the layer stack 601 is as follows: first of all the silicone layer 501 and only then the conversion layer 201.

In a manner similar to FIG. 3, a singulation step is provided according to FIG. 7 to form recesses 301 in the layer stack 601. A saw 701, for example, is provided for this singulation step. That is to say, the recesses 301 can be sawed using the saw 701, for example.

After this singulation step, singulated converter components 801 are therefore formed in a manner similar to FIG. 3, as shown in FIG. 8. One example not shown provides for the singulated converter components 801 to be electro-optically characterized in a manner similar to FIG. 4. This is affected, for example, by the light source 401 and the optical detector 403.

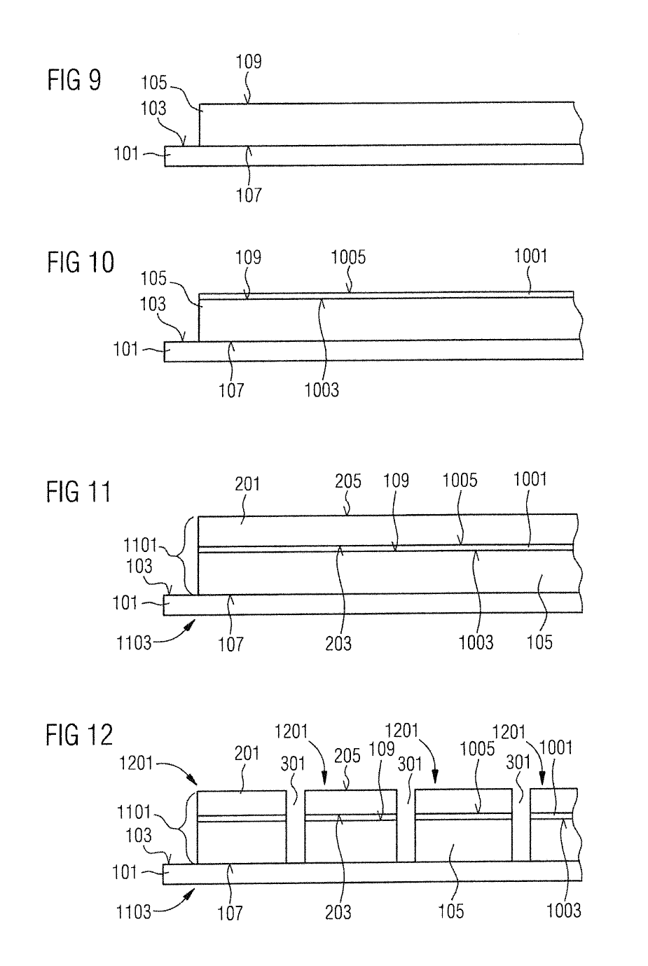

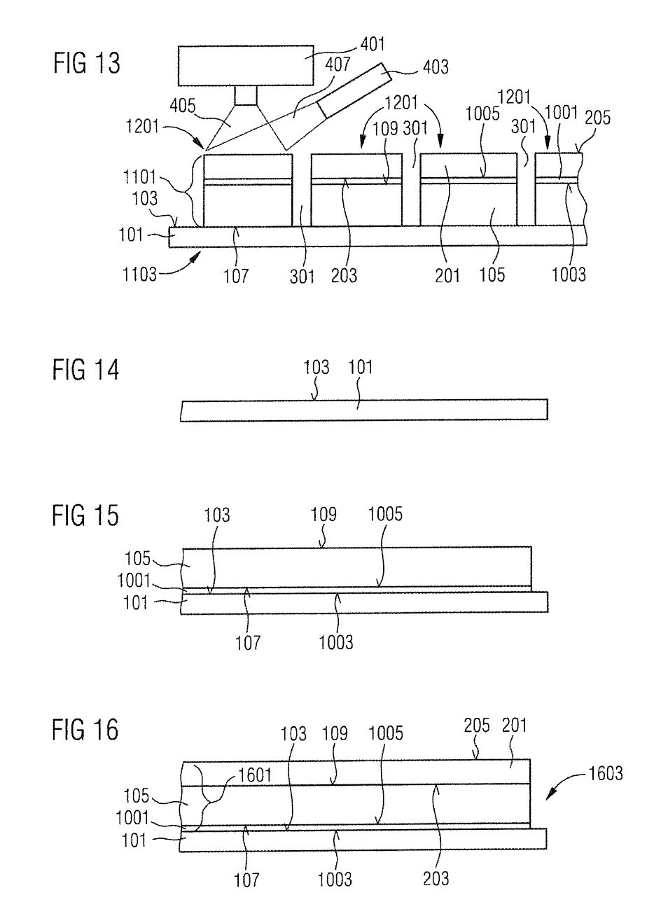

FIGS. 9 to 13 each show a production step in a method of producing a third converter component.

In a manner similar to FIG. 1, FIG. 9 shows a provided auxiliary carrier 101, a clear silicone layer 105 already having been applied to the surface 103 of the auxiliary carrier 101.

FIG. 10 shows that a diffuser layer 1001 is applied to the top side 109 of the silicone layer 105. The diffuser layer 1001 has an underside 1003 and a top side 1005 opposite the underside. The diffuser layer 1001 is applied to the silicone layer 105 such that the underside 1003 of the diffuser layer 1001 faces the top side 109 of the silicone layer 105. The top side 1005 of the diffuser layer 1001 faces away from the top side 109 of the silicone layer 105. That is to say, the silicone layer 105 is applied to the surface 103 as the first layer. The diffuser layer 1001 then follows.

The diffuser layer 1001 may comprise a plurality of diffuser particles, for example.

The diffuser layer 1001 may be sprayed on, for example.

FIG. 11 shows that a converter layer 201 is applied to, for example, sprayed onto the diffuser layer 1001. That is to say, the underside 203 of the converter layer 201 is arranged to face the top side 1005 of the diffuser layer 1001. The top side 205 of the converter layer 201 faces away from the top side 1005 of the diffuser layer 1001.

A layer stack 1101 comprising the silicone layer 105, the diffuser layer 1001 and the converter layer 201 is therefore formed.

A converter component 1130 comprising the auxiliary carrier 101 and the layer stack 1101 is therefore produced. Based on the auxiliary carrier 101, a sequence of the layers of the layer stack 1101 is as follows: first of all the silicone layer 105, then the diffuser layer 1001 and only then the converter layer 201.

In a manner similar to FIG. 3, FIG. 12 shows singulation of the layer stack 1101 that has already been carried out. The singulated converter components are provided with the reference symbol 1201.

In a manner similar to FIG. 4, electro-optical characterization is also provided for the singulated converter components 1201. This is affected, for example, using the light source 401 and the optical detector 403.

FIGS. 14 to 18 each show a production step in a method of producing a fourth converter component.

FIG. 14 shows a provided auxiliary carrier 101. A diffuser layer 1001 is first of all applied to, for example, sprayed onto the surface 103 of the auxiliary carrier 101 according to FIG. 15, and the silicone layer 105 is only then formed. That is to say, the underside 1003 of the diffuser layer 1001 faces the surface 103. The top side 1005 of the diffuser layer 1001 faces away from the surface 103. The underside 107 of the silicone layer 105 faces the top side 1005 of the diffuser layer 1001. The top side 109 of the silicone layer 105 faces away from the top side 1005 of the diffuser layer 1001.

FIG. 16 shows that a converter layer or conversion layer 201 is applied to, for example, sprayed onto the silicone layer 105. In this case, the underside 203 of the converter layer 201 faces the top side 109 of the silicone layer 105. The top side 205 of the converter layer 201 faces away from the top side 109 of the silicone layer 105. That is to say the converter layer 201 is applied to the top side 109 of the silicone layer 105.

A layer stack 1601 comprising the diffuser layer 1001, the silicone layer 105 and the converter layer 201 is therefore formed. This layer stack 1601 is therefore formed on the surface 103 of the auxiliary carrier 101.

A converter component 1603 comprising the auxiliary carrier 101 and the layer stack 1601 is therefore produced. Based on the auxiliary carrier, a sequence of the layers in the layer stack 1601 is as follows: first of all the diffuser layer 1001, then the silicone layer 105 and only then the converter layer or conversion layer 201.

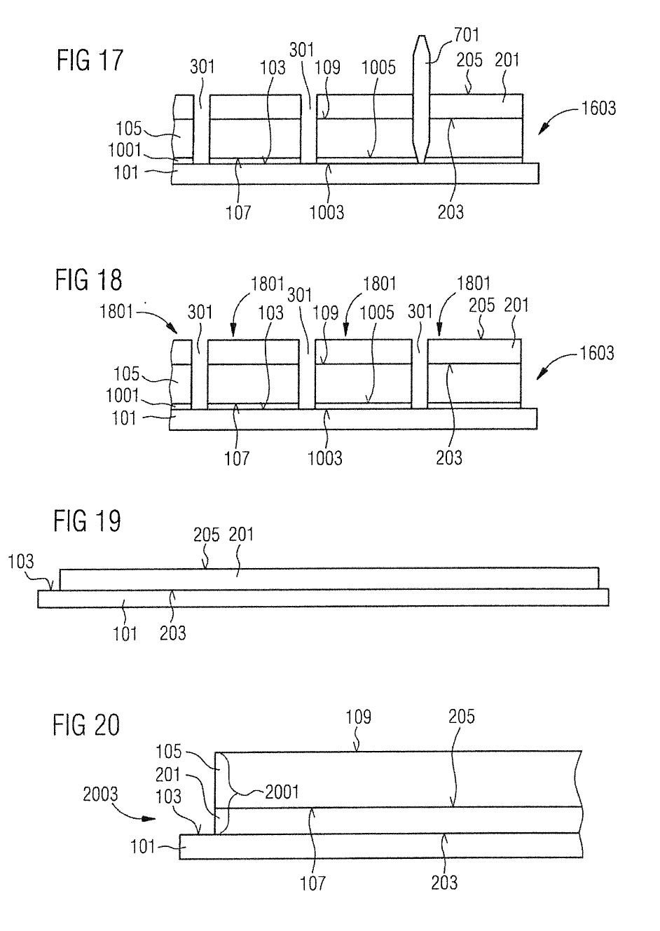

In a manner similar to FIG. 7, FIG. 17 shows singulation of the layer stack 1601 by a saw 701.

Singulated converter components 1801 are therefore formed according to FIG. 18. In a manner similar to FIG. 8, electro-optical characterization may then also be provided here.

FIGS. 19 to 22 each show a production step in a method for the production of or producing a fifth converter component.

FIG. 19 shows a provided auxiliary carrier 101, a converter layer 201 being applied to, for example, sprayed onto the surface 103. In this case, the underside 203 faces the surface 103. The top side 205 of the converter layer 201 faces away from the surface 103.

FIG. 20 shows that a silicone layer 105 is applied to the top side 205 of the converter layer 201. The silicone layer 105 is free of a diffuser. The underside 107 of the silicone layer 105 faces the top side 205 of the converter layer 201. The top side 109 of the silicone layer 105 faces away from the top side 205 of the converter layer 201.

A layer stack 2001 comprising the converter layer 201 and the silicone layer 105 is therefore formed. The layer stack 2001 is formed on the surface 103 of the auxiliary carrier 101.

A converter component 2003 comprising the auxiliary carrier 101 and the layer stack 2001 is therefore formed or produced. Based on the auxiliary carrier, a sequence of the layers of the layer stack 2001 is as follows: first of all the converter layer 201 and only then the silicone layer 105.

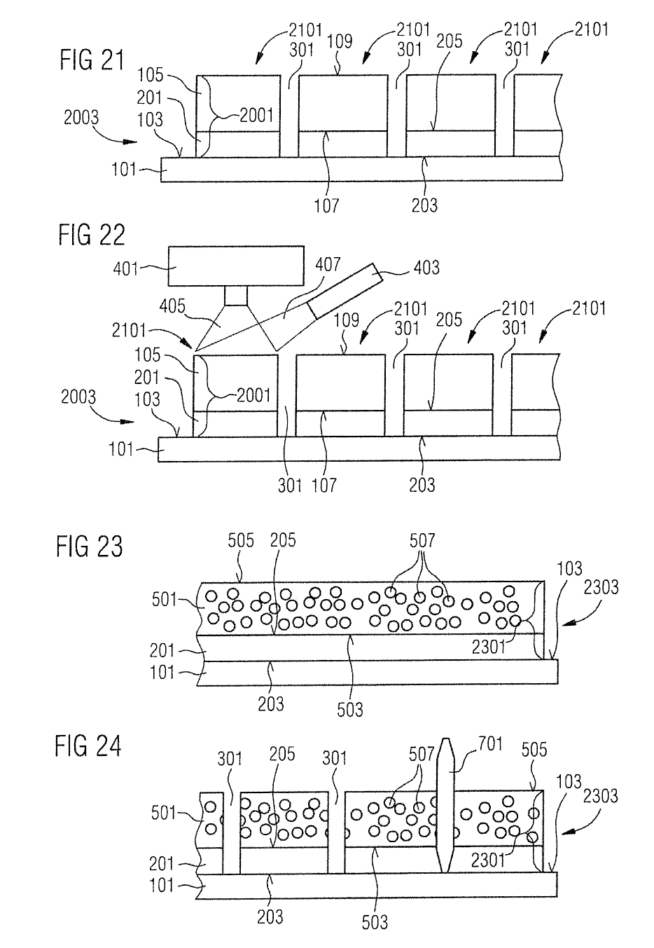

In a manner similar to FIG. 3, FIG. 21 shows singulated converter components 2101 as are formed after singulating the layer stack 2001 according to FIG. 20.

In a manner similar to FIG. 4, electro-optical characterization of the singulated converter components 2101 is provided in FIG. 22.

FIGS. 23 to 25 each show a production step in a method for the production of or producing a sixth converter component.

In a manner similar to FIG. 19, FIG. 23 starts from a provided auxiliary carrier comprising a converter layer 201.

A silicone layer 501 is applied to the top side 205 of the converter layer 201. In this case, the silicone layer 501 is diffuse, that is to say is not clear, that is to say has a diffuser. These are diffuser particles 507 here. A silicone layer 501 having diffuser particles 507 is therefore applied to the top side 205 of the converter layer 201. The underside 503 of the silicone layer 501 faces the top side 205 of the converter layer 201. The top side 505 of the silicone layer 501 faces away from the top side 205 of the converter layer 201.

A layer stack 2301 comprising the converter layer 201 and the silicone layer 501 is therefore formed. The layer stack 2301 is formed on the surface 103 of the auxiliary carrier 101.

A converter component 2303 comprising the auxiliary carrier 101 and the layer stack 2301 is therefore produced. Based on the auxiliary carrier 101, a sequence of the layers in the layer stack 2301 is as follows: first of all the converter layer 201 and only then the silicone layer 501.

In a manner similar to FIG. 7, FIG. 24 shows singulation of the layer stack 2301 by a saw 701.

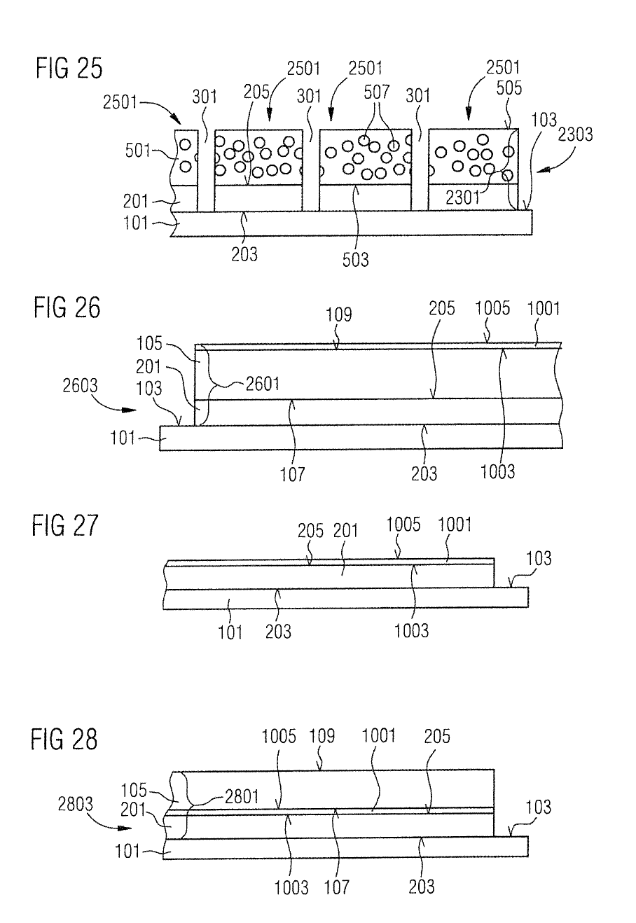

FIG. 25 shows the singulated converter components 2501 in a manner similar to FIG. 8. Electro-optical characterization of the singulated converter components 2501 can also be provided here.

FIG. 26 shows a production step in a method of producing a seventh converter component.

FIG. 26 here starts from the converter component 2003 according to FIG. 20. As a difference, a diffuser layer 1001 is applied to the top side 109 of the silicone layer 105. The underside 1003 of the diffuser layer 1001 therefore faces the top side 109 of the silicone layer 105. The top side 1005 of the diffuser layer 1001 faces away from the top side 109 of the silicone layer 105.

A layer stack 2601 comprising the converter layer 201, the silicone layer 105 and the diffuser layer 1001 is therefore formed. This layer stack 2601 is formed on the surface 103 of the auxiliary carrier 101.

A converter component 2603 comprising the auxiliary carrier 101 and the layer stack 2601 is therefore produced. Based on the auxiliary carrier, a sequence of the layers of the layer stack 2601 is as follows: first of all the converter layer 201, then the silicone layer 105 and finally the diffuser layer 1001.

In a manner similar to the statements made above, singulation and electro-optical characterization are also provided here, which is not shown again for the purpose of avoiding repetitions.

FIGS. 27 and 28 each show a production step in a method of producing an eighth converter component.

In a manner similar to FIG. 19, FIG. 27 starts from an auxiliary carrier 101 comprising a converter layer 201. A diffuser layer 1001 is applied to the top side 205 of the converter layer 201. In this case, the underside 1003 of the diffuser layer 1001 faces the top side 205 of the converter layer 201. The top side 1005 of the diffuser layer 1001 faces away from the top side 205 of the converter layer 201.

According to FIG. 28, a silicone layer 105 free of a diffuser is applied to the top side 1005 of the diffuser layer 1001. The underside 107 of the silicone layer 105 therefore faces the top side 1005 of the diffuser layer 1001. The top side 109 of the silicone layer 105 faces away from the top side 1005 of the diffuser layer 1001.

A layer stack 2801 comprising the converter layer 201, the diffuser layer 1001 and the silicone layer 105 is therefore formed. This layer stack 2801 is formed on the surface 103 of the auxiliary carrier 101.

A converter component 2803 comprising the auxiliary carrier 101 and the layer stack 2801 is therefore produced. Based on the auxiliary carrier 101, a sequence of the layers in the layer stack 2801 is as follows: first of all the converter layer 201, then the diffuser layer 1001 and finally the silicone layer 105.

In a manner similar to the statements made above, singulation is also provided for the converter component 2803. The singulated converter components are electro-optically characterized, in particular. The singulation and the characterization are not shown again for the purpose of avoiding repetitions.

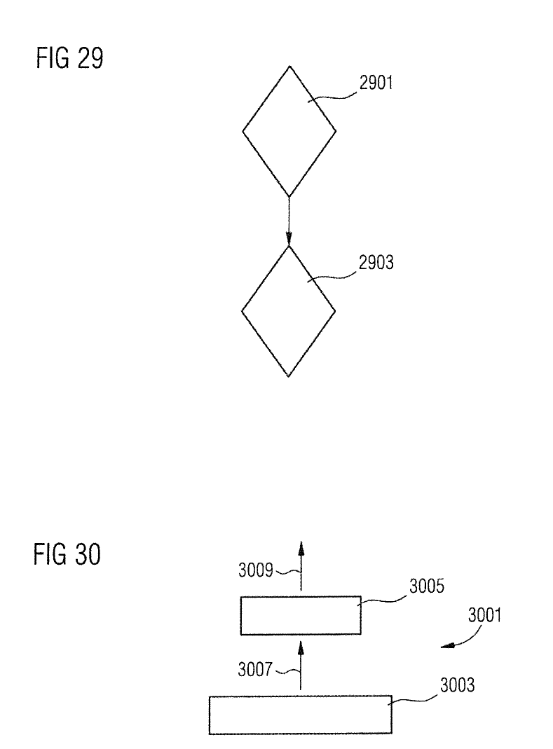

FIG. 29 shows a flowchart of a method for the production of or producing a converter component for an opto-electronic lighting device.

The method comprises the following steps of:

providing (2901) an auxiliary carrier, and

forming (2903) a layer stack comprising a silicone layer as a base layer and a converter layer on a surface of the auxiliary carrier.

FIG. 30 shows an opto-electronic lighting device 3001.

The opto-electronic lighting device 3001 comprises a light-emitting semiconductor component 3003, for example, a light-emitting diode in particular a laser diode. The light-emitting diode is an inorganic or organic light-emitting diode, for example.

The opto-electronic lighting device 3001 also comprises a converter component 3005 with a removed auxiliary carrier. That is to say, the converter component 3005 only comprises a layer stack. This layer stack can be formed according to one of the layer stacks described above.

During operation of the opto-electronic lighting device 3001, the light-emitting semiconductor component 3003 emits primary light 3007. This primary light 3007 is converted into secondary light 3009 by the converter component 3005.

We therefore provide, in particular and inter alia, the concept of using a plurality of technologies to produce films and/or continuous layers of producing a converter component. In particular, provision is therefore made for a silicone film, generally a silicone layer, with a defined layer thickness to be produced as a starting layer on an auxiliary carrier which may be in the form of a smooth auxiliary carrier, in particular. This film may be made of a clear silicone, for example, or may be filled with a diffuser, for example, with diffuser particles. Particles having an average particle size of 100 nm to 10 μm for example, are particularly suitable as diffuser particles. SiO₂ particles, Al₂O₃ particles, THIO₂ particles, silicone particles or glass particles, for example, are suitable as the material for diffuser particles.

The diffuser film or clear silicone film can preferably be produced or have been produced using known technologies, for example, printing, sheet drawing, rolling or molding. A decisive criterion for the film is the dimensional stability of the layer thickness which can be set, however, well and in a reproducible manner using the technologies mentioned above. The diffuser film or clear silicone film may be sprayed on, for example.

In a second step, one example provides for a mixture of silicone and a converter to be applied to the silicone layer, in particular silicone film, prepared in this manner. The mixture is preferably sprayed on, for example, by spray coating. The spraying-on, in particular the spray coating, provides a technology, on the basis of which both a layer thickness and a color location can be set well and in a reproducible manner. This applied mixture therefore forms a converter layer.

Alternatively, we provide for the diffuser, that is to say the diffuser particles, to be sprayed onto the clear silicone film in a separate step, rather than being embedded in the silicone film.

Further alternatively, we provide a reverse process in which the converter layer is applied to, in particular sprayed onto, the surface of the auxiliary carrier first. In a subsequent step, the clear silicone layer or the silicone layer filled with diffuser particles can be applied using the above-mentioned technologies, for example. In a clear silicone layer, another alternative may provide for the diffuser layer to be sprayed directly onto the converter layer or directly onto the clear silicone layer.

The film stack produced in this manner is singulated according to one example using separating technologies known per se, for example, punching, sawing or lasering or water jet cutting.

One example then provides for the singulated converter components to be characterized, for example, by an electro-optical measurement. In particular, yet further processing steps can be provided.

New possibilities for component-specific assembly advantageously emerge from exemplary use of two (or three) films produced with or without fillers (diffusers, converters).

Layer thicknesses can therefore be adapted according to the component requirements, the converters used and the color locations to be achieved.

There is the simple and efficient possibility of purchasing silicone films already commercially available on the market.

In addition to the very good contour fidelity, singulating the produced layers also entails the advantage of being able to adapt the dimensions relatively quickly.

Potting processes of the semiconductor component up to the upper edge of the conversion layer are possible as a result of the good contour fidelity (sharp outer edges).

The silicone surface of the converter components (also called conversion elements) formed on the (for example, smooth) auxiliary carrier guarantees a highly reproducible and homogeneous appearance.

The practice of spraying on the conversion layer allows a conversion layer having a very dense particle packing, having an advantageous effect on cooling and therefore a positive effect on the service life of the components.

Although our components and methods have been described and illustrated more specifically in detail by the preferred examples, this disclosure is not restricted by the examples and other variations can be derived therefrom by those skilled in the art without departing from the scope of protection of the appended claims.

This application claims priority of DE 10 2015 105 474.4, the subject matter of which is incorporated herein by reference.

1-19. (canceled)

20. A converter component for an opto-electronic lighting device, comprising:
an auxiliary carrier, wherein
a layer stack comprising a base layer and a converter layer is formed on a surface of the auxiliary carrier.

21. The converter component according to claim 20, wherein the base layer is free of a diffuser.

22. The converter component according to claim 20, wherein the base layer comprises a diffuser.

23. The converter component according to claim 20, wherein the layer stack comprises a diffuser layer comprising a diffuser.

24. The converter component according to claim 21, wherein the diffuser comprises one or more diffuser particles selected from the group consisting of SiO₂ particles, Al₂O₃ particles, THIO₂ particles, silicone particles and glass particles.

25. The converter component according to claim 20, wherein the converter layer comprises silicone and a converter.

26. The converter component according to claim 20, wherein at least one of the layers of the layer stack has been sprayed on.

27. The converter component according to claim 20, wherein the base layer is formed as a base film.

28. The converter component according to claim 20, wherein the base layer is formed as a silicone layer.

29. The converter component according to claim 20, wherein the layer stack is free of a diffuser layer comprising a diffuser.

30. A method of producing a converter component for an opto-electronic lighting device comprising:
providing an auxiliary carrier, and
forming a layer stack comprising a base layer and a converter layer on a surface of the auxiliary carrier.

31. The method according to claim 30, wherein the base layer is free of a diffuser.

32. The method according to claim 30, wherein the base layer comprises a diffuser.

33. The method according to claim 30, wherein the layer stack comprises a diffuser layer comprising a diffuser.

34. The method according to claim 31, wherein the diffuser comprises one or more diffuser particles selected from the group consisting of SiO₂ particles, Al₂O₃ particles, THIO₂ particles, silicone particles and glass particles.

35. The method according to claim 30, wherein the converter layer comprises silicone and a converter.

36. The method according to claim 30, wherein at least one of the layers of the layer stack is sprayed on.

37. The method according to claim 30, wherein the base layer is formed as a base film.

38. The method according to claim 30, wherein the base layer is formed as a silicone layer.

39. An opto-electronic lighting device comprising a light-emitting semiconductor component and the converter component according to claim 20 with a removed auxiliary carrier.
